(19) United States
(12) Patent Application Publication
(10) Pub. No.: US 2019/0234602 A1
(43) Pub. Date: Aug. 1, 2019

(54) ILLUMINATION MODULE ASSEMBLY

(71) Applicant: PANASONIC INTELLECTUAL PROPERTY MANAGEMENT CO., LTD., Osaka (JP)

(72) Inventors: Jurgen ECKERT, Kamp-Lintfort (DE); Martin PLACHTA, Kamp-Lintfort (DE); Robert NOKEN, Kamp-Lintfort (DE)

(73) Assignee: PANASONIC INTELLECTUAL PROPERTY MANAGEMENT CO., LT D., Osaka (JP)

(21) Appl. No.: 16/256,672

(22) Filed: Jan. 24, 2019

(30) Foreign Application Priority Data
Jan. 29, 2018 (DE) 102018101871.1

(51) Int. Cl. F21V 23/06; H05K 1/18; F21V 23/00; F21V 19/00

(52) U.S. Cl. CPC F21V 23/06; H05K 1/181; F21Y 2115/10; F21V 19/0045; F21V 23/006

(57) ABSTRACT

An illumination module assembly includes: a first housing part that includes a connector and a positioning window, and can be fastened to a base surface; a second housing part that includes a counterpart connector, which is configured to create a connection with the connector of the first housing part, and has an inner wall section bordering a light exit opening, an outer wall section, and a connecting wall section that connects the inner wall section and the outer wall section; and an operating circuit that includes at least one component being arranged on a component side of a printed circuit board. The printed circuit board is fastened to the second housing part and arranged between the inner wall section and the outer wall section, such that a printed circuit board bottom opposite the component side faces the connecting wall section.

### CROSS REFERENCE TO RELATED APPLICATION

This application claims the benefit of priority of German Patent Application Number 102018101871.1, filed on Jan. 29, 2018, the entire content of which is hereby incorporated by reference.

### TECHNICAL FIELD

The present disclosure relates to an illumination module assembly that includes an illumination module, for example a semiconductor illumination module, including a lamp assembly that can have one or more semiconductor lamps. The illumination module assembly includes a housing that is configured to be attached to a mounting surface or base surface.

### BACKGROUND ART

EP 2 633 232 B1 describes an illumination module assembly with a housing, an operating circuit arranged on a ring-shaped printed circuit board, and an illumination module consisting of a carrier plate and light-emitting diodes arranged in the middle of the carrier plate. The carrier plate is at least as large as the printed circuit board supporting the operating circuit. The printed circuit board has a central opening arranged in it, so that the printed circuit board is ring-shaped and surrounds the light-emitting diodes of the illumination module. The printed circuit board is put directly on the carrier plate, without an air gap. The carrier plate and the printed circuit board are arranged in a stack, so that the carrier plate simultaneously serves as a heat sink to dissipate heat from the printed circuit board.

### SUMMARY

It can be considered the goal of the present disclosure to create an illumination module assembly that allows improved handling and/or simplified assembly.

This is accomplished by an illumination module assembly having the features of claim 1.

The inventive illumination module assembly includes a housing that includes a first housing part and a second housing part. The first housing part includes a connector that can interact with a counterpart connector of the second housing part to make a connection between the two housing parts. The connection can be in the form of a detachable latching connection. The connection or latching connection is, in particular, made and/or undone without tools.

The first housing part has a positioning window for an illumination module. The positioning window goes completely through the first housing part. The first housing part is configured to be fastened to a base surface using a fastening component. The fastening component can include, for example, screws to make a screw connection. An illumination module inserted into the positioning window lies with its back surface against the base surface, this back surface facing away from the light emission side. For example, the illumination module is not solidly connected with the first housing part. The heat of the illumination module can be released directly to the base surface, without interposition of the housing.

The second housing part has an inner wall section, an outer wall section surrounding the inner wall section in a peripheral direction, and a connecting wall section that connects the inner wall section and the outer wall section. The inner wall section borders a light exit opening.

The illumination module assembly also includes an operating circuit to operate the illumination module, this operating circuit having at least one component. In one exemplary embodiment, the operating circuit is configured for limitation and/or open-loop control and/or closed-loop control of an output current that is output to the illumination module. The operating circuit can also have other or additional control tasks or functions. For example, the operating circuit can have a detection circuit to detect the presence of persons in a detection area, and to turn the illumination module on or off.

The operating circuit has one or more components. The components are arranged on a printed circuit board. For example, all components may be located on the component side of the printed circuit board. The bottom of the printed circuit board, opposite the component side, may be free of components. The printed circuit board is fastened to the second housing part, for example by friction and/or in a form-fit manner and/or by an adhesive connection. The printed circuit board is arranged in such a way between the inner wall section and the outer wall section that the printed circuit board bottom faces the connecting wall section.

This design means that the illumination module assembly has a few units that must be handled during assembly. The printed circuit board with the operating circuit is fastened to the second housing part, and forms a common unit with the second housing part. The printed circuit board with the operating circuit can be injection molded into the second housing part, forming the common unit with the second housing part. After the first housing part is fastened to the base surface and the illumination module is inserted into the positioning window, it is only necessary to make the connection, for example a latching connection, between the two housing parts, in order to complete mechanical assembly of the lamp assembly.

It is also possible to make the connection or latching connection detachable, ensuring in this way simple accessibility to the illumination module, for example if the illumination module should be replaced by another illumination module. If the second housing part is removed—together with the operating circuit—from the first housing part, the first housing part remains fastened to the base surface. This achieves simple on-site handling of the illumination module assembly.

For example, the printed circuit board bottom may lie against or may be connected with the connecting wall section. In particular, the printed circuit board bottom can lie against or make indirect or direct contact with the connecting wall section over an extensive area. For example, the printed circuit board bottom can be connected with the connecting wall section by an adhesion-promoting connection. This can form an adhesive joint between the printed circuit board bottom and the connecting wall section.

It is advantageous if the printed circuit board and the at least one component of the operating circuit are arranged completely within an installation space. The installation space is defined by the inner wall section, the outer wall section, and the connecting wall section of the second housing part. The printed circuit board and the at least one component are arranged completely within this installation space, and do not project through a limiting plane. In one exemplary embodiment, the limiting plane is oriented parallel to the connecting wall section and touches the lower edge of the outer wall section and/or of the inner wall section, this lower edge being opposite the connecting wall section. The installation space can be ring-shaped and closed in the peripheral direction, or it can have multiple individual installation space sections, which do not directly border one another. Such installation space sections can have at least one holding area between them to hold an electrically conductive connection element.

The first housing part and/or the second housing part may each be made as an integral part without a seam or joint from a uniform material, in particular from a synthetic material or another electrically non-conductive material.

In an exemplary embodiment, the second housing part has at least one electrical connection socket. Adjacent to every electrical connection socket there is a holding area that is arranged between the inner wall section and the outer wall section. Every holding area is configured to hold one connection element, which can be arranged there by friction and/or in a form-fit manner, for example, in a detachable manner. The connection element is configured to make an electrical connection between a conductor inserted into the connection socket and the operating circuit.

For example, at least one or two holding areas may each have a connection element arranged in it/them. The second housing part has, for example, two, three, four, or even more connection areas, each with an associated connection socket.

In one exemplary embodiment, every connection element has an electrical clamping assembly that is arranged aligned behind an insertion opening of the respective connection socket in an insertion direction of the associated connection socket and that can clamp a conductor stuck through the connection socket, to make a mechanical and electrical connection to the conductor.

Moreover, it is advantageous if the component side of the printed circuit board has electrically conductive printed circuit board contact surfaces on it. The printed circuit board contact surfaces are electrically connected with the operating circuit through conductors or conductor tracks on or in the printed circuit board. At least one of the printed circuit board contact surfaces represents an input connection of the operating circuit. At least one of the printed circuit board contact surfaces represents an output connection of the operating circuit, each of these at least one output connections being electrically connectable with the illumination module through an electrically conductive contact element.

For example, every connection element may have a contact part. The contact part lies against an associated electrically conductive printed circuit board contact surface of the printed circuit board, this contact surface forming an input connection for the operating circuit. Thus, the connection element allows an electrical connection to be made between the printed circuit board contact surface of the printed circuit board and a conductor inserted into the connection socket.

For example, every connection element may be held by friction and/or in a form-fit manner in the respective holding area on the second housing part, for example on the inner wall section and/or on the outer wall section, or clamped between them.

In one exemplary embodiment, the contact element has a first contact section that is electrically connected with an associated printed circuit board contact surface. Optionally, it is also possible for a mechanical connection to be made between the printed circuit board contact surface and the first contact section, in addition to the electrical connection, for example by making a soldered connection between the first contact section and the associated printed circuit board contact surface. The contact element can have, extending away from the first contact section, a contact spring, which has, on the end opposite the first contact section, a second contact section of the contact element. The second contact section is configured to lie against a module contact surface module contact surface of the illumination module, if the connection is made between the two housing parts when the illumination module is inserted in the positioning window. For example, the contact spring may be elastically movable in the direction toward the positioning window or away from the positioning window. In the assembled state, this can produce a contact pressure between the second contact section and an associated module contact surface of the illumination module.

### BRIEF DESCRIPTION OF THE DRAWINGS

The figures depict one or more implementations in accordance with the present teaching, by way of examples only, not by way of limitations. In the figures, like reference numerals refer to the same or similar elements.

FIG. 1 is a perspective representation of an exemplary embodiment of an illumination module assembly showing the light emission side of an illumination module;

FIG. 2 is another perspective representation of the illumination module assembly from FIG. 1 showing the attachment side of the illumination module assembly;

FIG. 3 is a schematic exploded view of the illumination module assembly from FIG. 1 and FIG. 2;

FIG. 4 is a perspective representation of a second housing part of the illumination module assembly according to FIG. 1 to FIG. 3, showing an installation space;

FIG. 5 is a perspective representation of an exemplary embodiment of an electrically conductive combined connection and contact element of the illumination module assembly;

FIG. 6 is a perspective representation of an exemplary embodiment of an electrically conductive connection element of the illumination module assembly;

FIG. 7 is the connection element from FIG. 6 in a top view along arrow VII when an electrical connection has been made with a conductor;

FIG. 8 is a perspective representation of a modified exemplary embodiment of the connection element;

FIG. 9 is a perspective representation of an exemplary embodiment of an electrically conductive contact element of the illumination module assembly;

FIG. 10 is the contact element from FIG. 9 in a top view along arrow X;

FIG. 11 is a cross sectional representation of the illumination module assembly according to FIG. 1 to FIG. 4;

FIG. 12 is an exemplary embodiment of an operating circuit with a printed circuit board and, arranged on it, a combined connection and contact element according to FIG. 5, a connection element according to FIG. 8, and contact elements according to FIG. 9 and FIG. 10;

FIG. 13 is an exemplary embodiment of an operating circuit with a printed circuit board and, arranged on it, connection elements according to FIG. 8 and contact elements according to FIG. 9 and FIG. 10; and

FIG. 14 is a block diagram-like representation of the electrical connection, through contact elements, of an operating circuit of the illumination module assembly with an illumination module, and through connection elements, with an external power source.

### DETAILED DESCRIPTION

### Embodiment

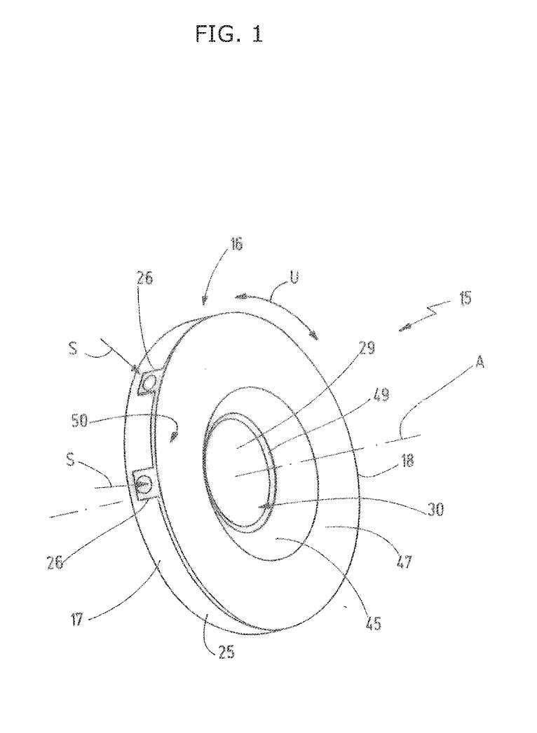

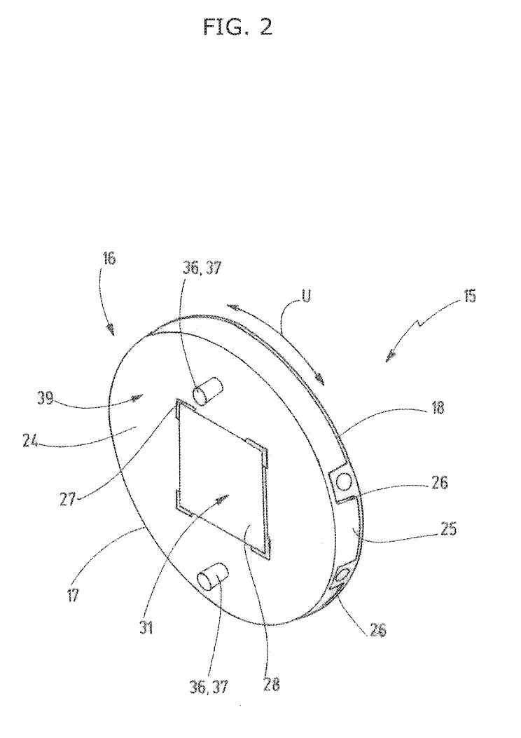

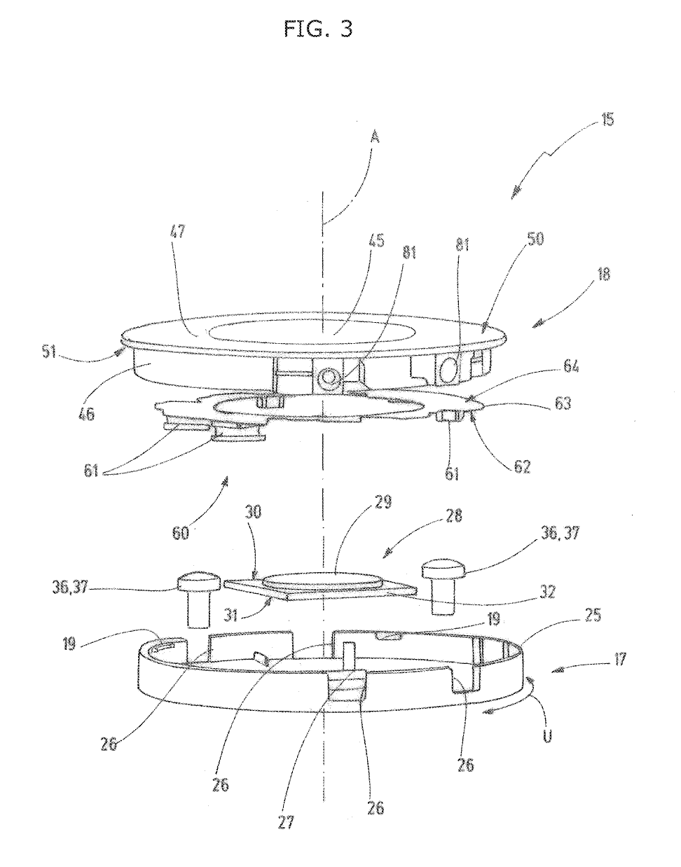

FIG. 1 to FIG. 4 and FIG. 11 are various views of an exemplary embodiment of an illumination module assembly 15. The illumination module assembly 15 includes a housing 16 having a first housing part 17 and a second housing part 18. According to the example, the housing 16 consists of only two housing parts 17, 18. The two housing parts 17, 18 are connectable with one another, preferably detachably connectable. The connection can be made without tools and separated again without tools or with the help of a tool. For this purpose, the first housing part 17 has connectors 19, which interact with counterpart connectors 20 of the second housing part 18, to make the connection. In the exemplary embodiment, the connection between the two housing parts 17, 18 is made by a latching connection.

The first housing part 17 has a housing bottom 24, which is surrounded by a peripheral wall 25 that goes around its outer edge in a peripheral direction U. The peripheral direction U is oriented about an optical axis A of the illumination module assembly 15. The peripheral wall 25 is ring-shaped, and can be closed in the peripheral direction U or it can have individual peripheral wall sections that are spaced in the peripheral direction U. The peripheral wall U has two or more wall openings 26, which are open on the side opposite the housing bottom 24 and completely pass through the peripheral wall 25 when viewed at right angles or radially to the optical axis A.

The housing bottom 24 has an opening in it, which represents a positioning window 27 to hold an illumination module 28 of the illumination module assembly 15. The illumination module 28 includes a lamp assembly 29, which can have one or more semiconductor lamps, for example light-emitting diodes (LEDs) or organic light-emitting diodes (OLEDs). The lamp assembly 29 is arranged on a light emission side 30 of the illumination module 28. On the side opposite the light emission side 30, the illumination module 28 has a module bottom 31. In the exemplary embodiment, the lamp assembly 29 is arranged on the top of a module carrier plate 32. The bottom of the module carrier plate 32, this bottom being opposite the top, forms the module bottom 31 of the illumination module 28.

The illumination module assembly 15 includes fastening components 36, each of which is formed, according to the example, by a screw 37. The fastening components 36 are configured to fasten the first housing part 17 to a base surface 38 in a detachable manner. If the second housing part 17 is attached, by the fastening components 36, to the base surface 38 (FIG. 11), an assembly side 39 of the housing bottom 24 lies against the base surface 38.

In the assembled state, the illumination module 28 is inserted in the positioning window 27 of the first housing part 17. The module bottom 31 lies indirectly or directly against the base surface 38, forming a thermally conductive connection. Optionally, a heat conduction foil 40 can be arranged between the module bottom 31 and the base surface 38, to improve heat transfer (FIG. 11).

The peripheral wall 25 projects away from the housing bottom 24 and on the assembly side 39 it does not stick out beyond the housing bottom 24. At a distance from the housing bottom 24 and, according to the example, abutting an upper edge of the peripheral wall 25, there are, at each of multiple places around the peripheral direction U, connectors 19 that are formed, according to the example, by latch lugs 41 projecting away from the peripheral wall 25 in the transverse direction and toward the optical axis A. According to the example, there are four latch lugs 41, which are arranged at a distance from one another in the peripheral direction U. The latch lugs 41 can be arranged in depressions in the peripheral wall 25, so that they do not project out beyond the peripheral wall 25 in the radial direction or at right angles to the optical axis A.

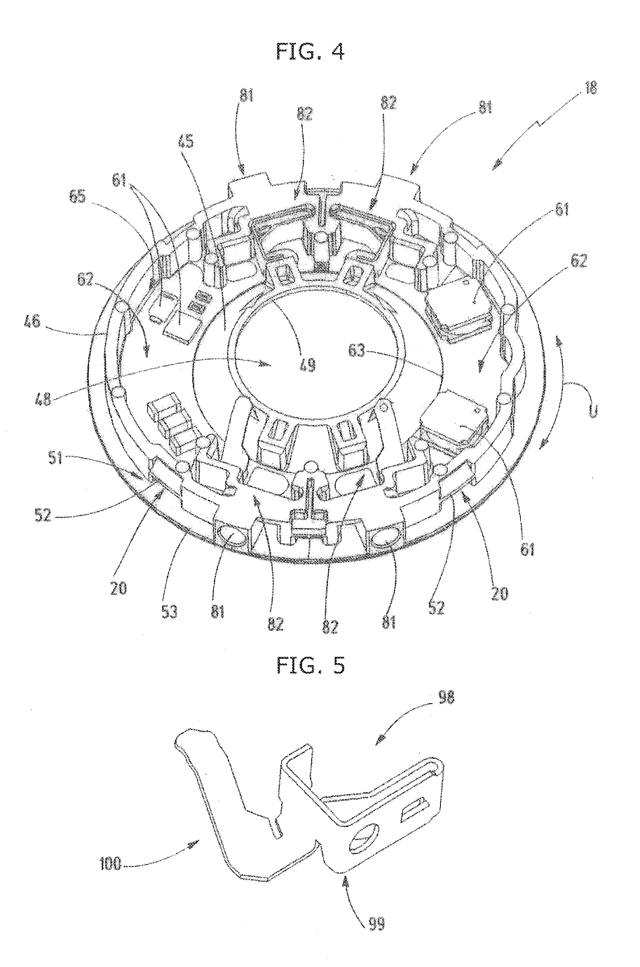

The second housing part 18 can be seen especially well in FIG. 4. This second housing part 18 has an inner wall section 45, an outer wall section 46 arranged at a distance from the inner wall section 45 in the radial direction with respect to the optical axis A, and a connecting wall section 47, which connects the inner wall section 45 with the outer wall section 46. The inner wall section 45 is ring-shaped and is closed in the peripheral direction U, and it borders a light exit opening 48 in the second housing part 18. The light exit opening 48 is centrally arranged in the area of the optical axis A, and is configured so that the light emitted from the illumination module 28 can exit from the housing 16 through the light exit opening 48. The dimension of the light exit opening 48 is at least as large as that of the lamp assembly 29. According to the example, multiple semiconductor lamps of the lamp assembly 29 are arranged on an essentially circular surface on the module carrier plate 32. The diameter of the light exit opening 48 is greater than the diameter of the lamp assembly 29 (FIG. 1 and FIG. 11).

The inner wall section 45 forms an inner edge 49 to border the light exit opening 48. Starting from this inner edge 49, the inner wall section 45 extends radially outward at an angle to the optical axis A, and on its side opposite the inner edge 49 it merges into the connecting wall section 47. In the exemplary embodiment, the connection wall section 47 extends essentially radially to the optical axis A. Thus, the inner wall section 45 has a shape corresponding to the lateral surface of a frustum of cone. Starting from the inner edge 49, the distance of the inner wall 45 from the optical axis A increases.

The connecting wall section 47 has a front surface 50 facing away from the base surface 38 or the first housing part 17, this front surface 50 being completely closed according to the example. Projecting away from a back surface 51 opposite the front surface 50 is the outer wall section 46. The outer wall section 46 surrounds the inner wall section 45 in the shape of a ring in the peripheral direction U, and according to the example does so essentially completely. The distance of the outer wall section 46 from the optical axis A is less than the distance of the peripheral wall 25 from the optical axis A, so that to make the connection the second housing part 18 with the outer wall section 46 can project into the inner area of the first housing part 17 bordered by the peripheral wall 25. According to the example, the counterpart connectors 20 are arranged at a distance from the connecting wall section 47 and are formed by radial projections, which project radially outward, away from the optical axis A. When the latching connection has been made (see FIG. 11), the connectors 19 or the latch lugs 41 project into a space between the counterpart connectors 20 and the connecting wall section 47, making the latching connection. The radial projections of the counterpart connectors 20 can be referred to as latch lug counterparts 52.

The connecting wall section 47 forms a peripheral edge 53 that covers or overlaps the peripheral wall 25 when the connection is made between the two housing parts 17, 18. According to the example, this is accomplished by the outside diameter of the connecting wall section 47 being greater than that of the outer wall section 46 and that of the counterpart connectors 20. The outside diameter of the connecting wall section 47 essentially corresponds to the outside diameter of the peripheral wall 25.

In the exemplary embodiment, the first housing part 17 and the second housing part 18 are each made in a single integral piece, and consist of an electrically non-conductive material, in particular, plastic.

The illumination module assembly 15 includes an operating circuit 60 with one or more electrical or electronic components 61. The at least one component 61 is arranged on a component side 62 of a printed circuit board 63. According to the example, the printed circuit board bottom 64 opposite the component side 62 is free of components 61.

The printed circuit board 63 is connected with the second housing part 18, for example by friction and/or in a form-fit manner and/or by an adhesion-promoting connection, such as, for instance an adhesive connection. For example, the printed circuit board bottom 64 can be connected with the back surface 51 of the connecting wall section 47 by an adhesion-promoting connection. In the exemplary embodiment, the printed circuit board 63 has a closed shape similar to a ring. The printed circuit board 63 is arranged in an installation space 65 that is bordered by the inner wall section 45, the outer wall section 46, and the connecting wall section 47. Neither the printed circuit board 63 nor one of the components 61 projects out of the installation space 65. In particular, no component 61 projects away from the component side 62 through a plane E that is oriented at right angles to the optical axis A and that lies against the inner edge 49 of the inner wall section 45 and/or that edge of the outer wall section 46 that is opposite the connecting wall section 47 (FIG. 11).

The inner wall section 45 is conical, so the radial dimension of the installation space 65 increases starting from the connecting wall section 47 in the direction toward the first housing part 17. The at least one component 61 can extend away from the component side 62 and the connecting wall section 47 into the installation space 65. This allows an especially space-saving arrangement of the operating circuit 60.

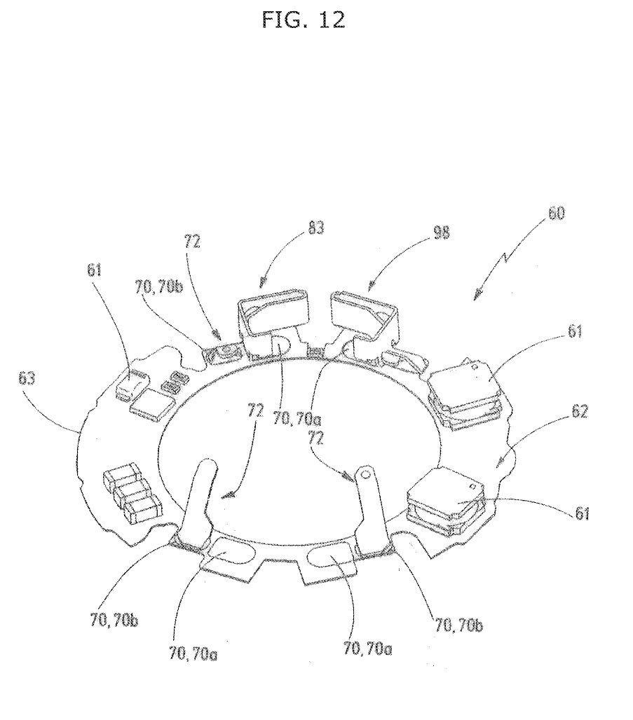

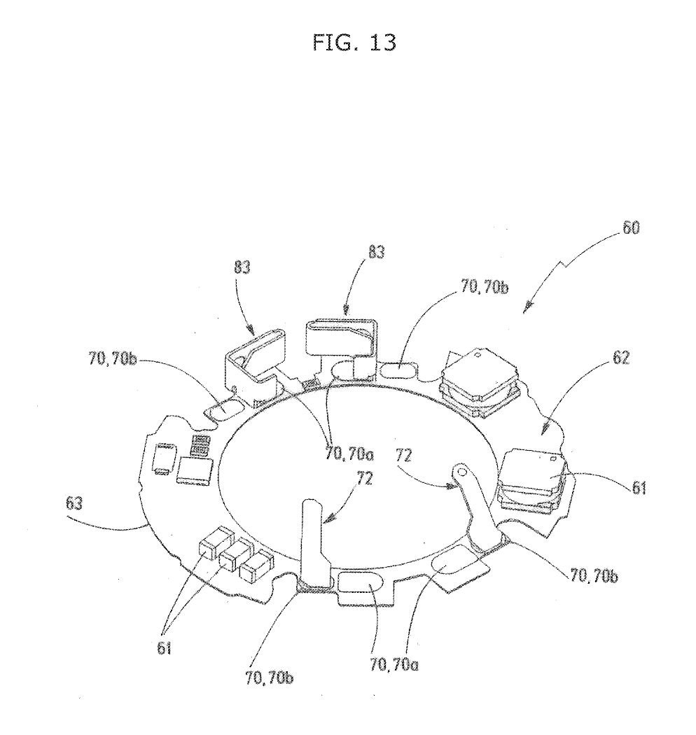

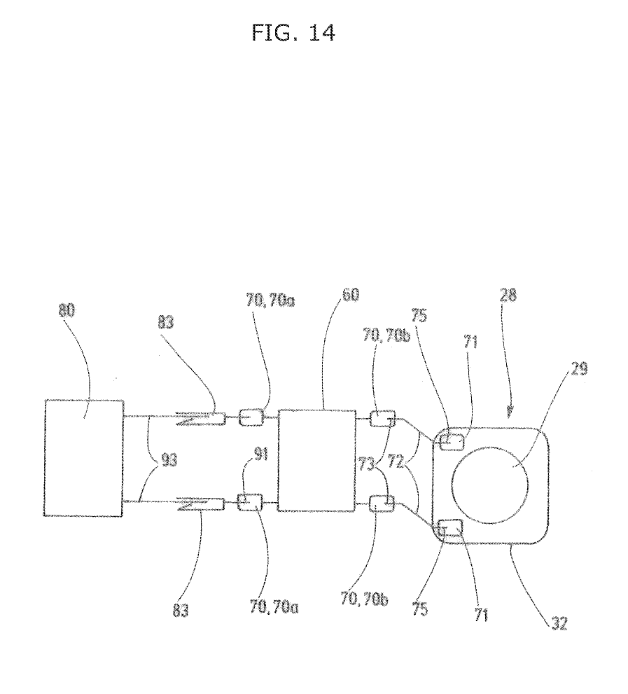

The component side 62 of the printed circuit board 63 has multiple electrically conductive printed circuit board contact surfaces 70 on it. At least one or two of these printed circuit board contact surfaces 70 represent the input connection(s) of the operating circuit 60 and are referred to as first printed circuit board contact surfaces 70a. At least one or two of the printed circuit board contact surfaces 70 represent the output connection(s) of the operating circuit 60 and are referred to as second printed circuit board contact surfaces 70b. The first and second printed circuit board contact surfaces 70a, 70b are illustrated in the perspective views of the operating circuit 60 (FIG. 12 and FIG. 13) and in the block diagram-like representation in FIG. 14.

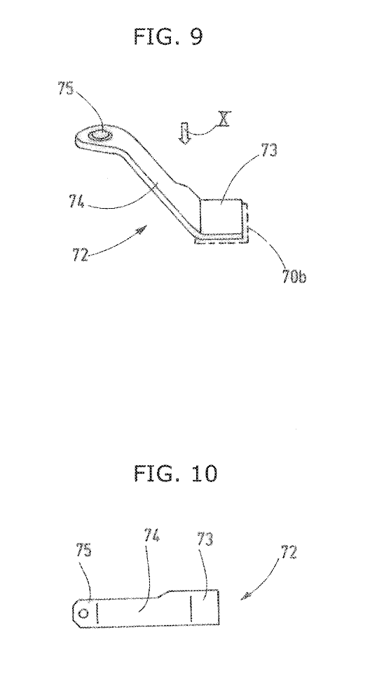

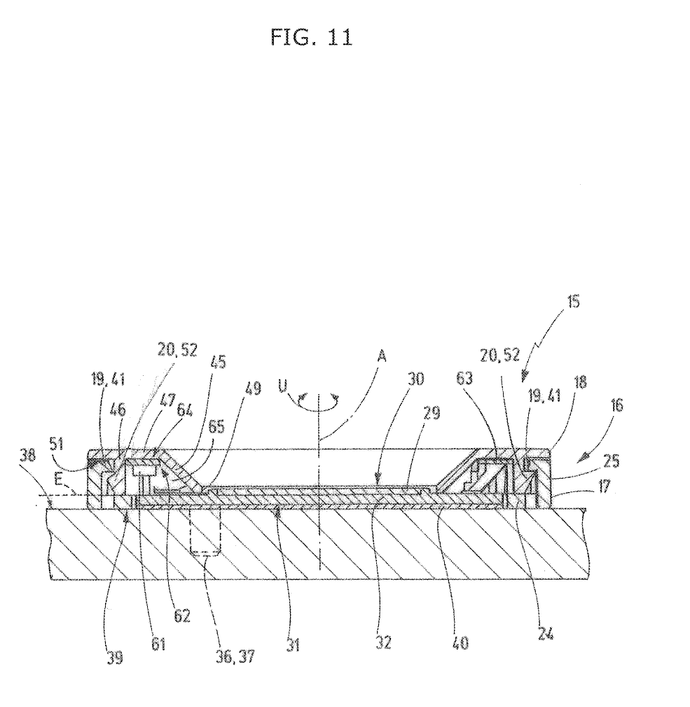

The illumination module 28 has at least two electrically conductive module contact surfaces 71 arranged on its light emission side 30, these electrically conductive module contact surfaces 71 being adjacent to the lamp assembly 29. Each second printed circuit board contact surface 70b is electrically connected with a respective module contact surface 71 by one electrically conductive contact element 72 for each electrical connection. An exemplary embodiment of a contact element 72 is illustrated in FIG. 9 and FIG. 10. The contact element 72 has a first contact section 73, which is associated with the printed circuit board 63. Each first contact section 73 is electrically connected with one second printed circuit board contact surface 70b. In the exemplary embodiment, this connection can be made by a soldered connection. This simultaneously allows a mechanical connection to be made between the contact element 72 and the printed circuit board 63. According to the example, the contact element 72 is mechanically held on the printed circuit board 63. In addition to or as an alternative to the soldered connection, this mechanical connection can also be achieved by a plug-and-socket connection or a latching connection.

The contact element 72 has a contact spring 74 that projects away from the first contact section 73 and that has, at its end, a second contact section 75. The contact spring 74 runs at an inclined angle away from the printed circuit board 63. At the transition to the contact sections 73, 75, the contact element 72 is at an angle or bent. This makes the contact element 72 elastic so that the second contact section 75 is mounted so that it can pivot under a certain spring action of the contact spring 74, and the distance from the second contact section 75 to the printed circuit board 63 can change. When the connection is made in the assembled state, the second contact section 75 lies against the associated module contact surface 71 of the illumination module 28, the contact spring 74 being able to provide a certain contact pressure of the second contact section 75 against the module contact surface 71. This achieves a good electrical connection and also presses the illumination module 28 against the base surface 38.

Thus, making the connection between the second housing part 18 and the first housing part 17 when an illumination module 28 is inserted in the positioning window 27 can make an electrical connection between the illumination module 28 and the operating circuit 60. The electrical connection is schematically illustrated by the block diagram in FIG. 14.

It is also necessary to provide the operating circuit 60 with the capability of making an electrical connection with an external power supply device 80. The power supply device 80 provides electric power for the operating circuit 60. The operating circuit 60 can place the electric power that is provided for operating the lamp assembly 29 under open-loop control and/or closed-loop control and/or limit it. For example, the operating circuit 60 can use the electric power provided by the power supply device 80 on the input side to provide the second printed circuit board contact surfaces 70b on the output side with an output direct current whose current intensity can be placed under open-loop control and/or closed-loop control and/or limited.

On the output side, the operating circuit 60 can have at least one, preferably two or more than two second printed circuit board contact surfaces 70b, each of which is electrically connected with module contact surfaces 71 of the illumination module 28 when the illumination module assembly 15 is assembled. Thus, it is possible; for example, for other signal lines in addition to the power supply to be electrically connected, to transfer control information or status information such as temperature measurements between the illumination module and the operating circuit. In another exemplary embodiment, an illumination module 28 of the illumination module assembly 15 can also have multiple individually controllable channels, for example it can be in the form of a dual-channel illumination module 28 (e.g., so-called “tunable white”) with three or four module contact surfaces 71. Accordingly, the printed circuit board 63 has three, four, or even more second printed circuit board contact surfaces 70b, one for each module contact surface 71. To supply power and control the operating circuit 60, the printed circuit board 63 can also have two or more first printed circuit board contact surfaces 70a, to be able, for example, to receive separate signals for multiple channels of the illumination module 28 and/or control information and/or status information.

For electrical connection with the power supply device 80, the printed circuit board 63 has—as explained above—the first printed circuit board contact surfaces 70a. The second housing part 18 has at least two, according to the example four connection sockets 81, which completely pass through the outer wall section 46 at right angles to or radial to the optical axis A. When the two housing parts 17, 18 are connected, an outer opening of every connection socket 81 is arranged in the area of a wall opening 26 of the peripheral wall 25 and is thus is accessible from outside. The opposite inner opening of every connection socket 81 opens into the area between the outer wall section 46 and the inner wall section 45, where there is, following this inner opening, a holding area 82, each of these holding areas 82 having one electrically conductive connection element 83. The holding area is arranged, so to speak, behind the connection socket 82 in an insertion direction (S) (FIG. 1). The holding areas 82 are designed and configured so that one connection element 83 can be arranged in each. In particular, the inner wall section 45 and/or the outer wall section 46 bordering the holding area 82 is/are designed so that in each case one connection element 83 can be fastened to the second housing part 18 by friction and/or in a form-fit manner, preferably detachably so.

The printed circuit board 63 extends both in the installation space 65, and also into the holding areas 82. The holding areas 82 need not necessarily have components 61 of the operating circuit 60 arranged within them. According to the example, the holding areas 82 are kept clear for arranging the connection elements 83.

The printed circuit board 63 has a first printed circuit board contact surface 70a in the area of at least one or two of the holding areas 82 that are present. The associated holding area 82 can have a connection element 83 arranged in it, to make an electrical connection with the associated first printed circuit board contact surface 70a.

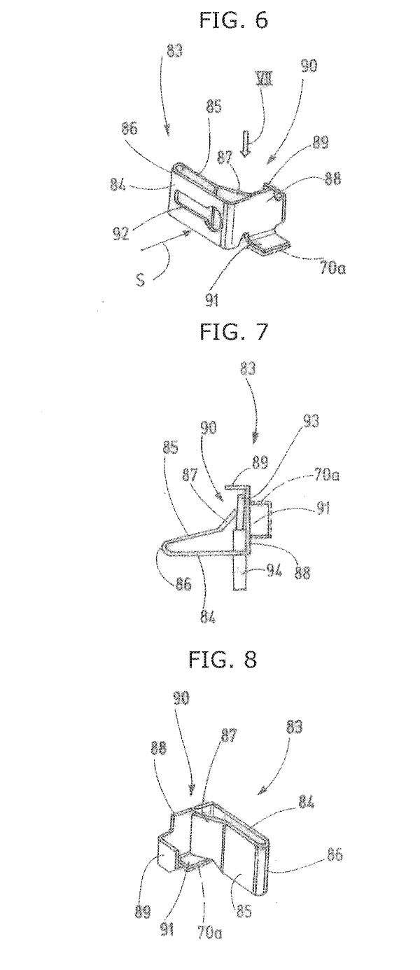

Exemplary embodiments of connection elements 83 are illustrated in FIG. 6, FIG. 7, and FIG. 8.

FIG. 6 and FIG. 7 show a first exemplary embodiment of the connection element 83. The connection element 83 has a plate-shaped first leg 84 and a plate-shaped second leg 85, these two legs being connected with one another through a curved connecting section 86 and being spaced apart from one another. On the side opposite the connecting section 86, the second leg 85 has an end section that is bent with respect to the second leg 85 and that forms a clamping part 87. The clamping part 87 extends at an angle away from the first leg 84.

The first leg 84 has, at its end opposite the connecting section 86, a transverse tab 88, which is oriented essentially at right angles to the first leg 84. This transverse tab 88 is followed, on the side opposite the first leg 84, by an end piece 89, which is bent with respect to the transverse tab 88 and which extends approximately parallel to the first leg 84. The clamping part 87 is arranged in the area between the first leg 84 and the end piece 89 and lies against the transverse tab 88 or is arranged at a distance from the transverse tab 88. The two legs 84, 85 can be elastically bent away from one another through the connecting section 86, so that the clamping part 87 is mounted in an elastically pivotable manner. The elastically mounted clamping part 87 forms, together with the transverse tab 88, a clamping assembly 90.

The connection element 83 also has a contact part 91, that is configured to lie against a first printed circuit board contact surface 70a, if the connection element 83 is inserted in the holding area 82. According to the example, the contact part 91 is connected with the transverse tab 88 and projects approximately at right angles to the transverse tab 88 and the legs 84, 85 in the area of the bottom of the connection element 83. Alternatively, the contact part 91 could also be arranged, for example, on the first leg 84.

In the exemplary embodiment according to FIG. 6 and FIG. 7, the contact part 91 projects away on the side of the transverse tab 88 opposite the clamping part 87. Alternatively, it is also possible that the contact part 91 projects away from transverse tab 88 in such a way that it is arranged between the first leg 84 and the end piece 89 and reaches under the clamping part (FIG. 8). This can achieve a space-saving arrangement on the printed circuit board 63. In other respects, the connection element 83 according to FIG. 8 corresponds to the embodiment described in connection with FIG. 6 and FIG. 7.

As can be seen especially in FIG. 6, the connection element 83 has an insertion opening 92 that passes through the first leg 84. The insertion opening 92 allows an electrically conductive conductor 93 to be introduced through the first leg 84 and between the clamping part 87 and the transverse tab 88, as is schematically shown in FIG. 7. When this happens, the second leg 85 gives way about the connection area 86 and produces a clamping force between the clamping part 87 and the transverse tab 88, this clamping force pressing on the conductor 93 and clamping it between the clamping part 87 and the transverse tab 88. This makes an electrically conductive connection between the conductor 93 and the connection element 83 and, through the contact part 91, with the first printed circuit board contact surface 70a.

As is illustrated in FIG. 7, the conductor 93 can be electrically insulated with a jacket 94 outside the clamping assembly 90. For example, an exposed conductor 93 at the end of a cable can be inserted through the connection socket 81, making an electrical connection with the connection element 83, as was explained above. Special electrical plugs and sockets that are electrically suitable for them are unnecessary, and are not provided.

FIG. 5 illustrates an exemplary embodiment of a combined connection and contact element 98. The connection and contact element 98 has a first part 99, which corresponds to the connection element 83 and a second part 100, which corresponds to the contact element 72. The contact part 91 of the connection element 83 is connected with the first contact section 73 of the contact element 72, in particular it is connected in a single piece, forming the combined connection and contact element 98. This combined connection and contact element 98 can be inserted into a holding area 82, where it then lies against both a first printed circuit board contact surface 70a, and also against a second printed circuit board contact surface 70b. This can electrically connect both the operating circuit 60 and also the illumination module 28 with the same conductor 93. This can, for example, provide both the operating circuit 60 and also the illumination module 28 with a reference potential, for example a negative potential or a ground potential. Other signals or potentials which can be required or used both in the operating circuit 60 and also on the illumination module 28 can also be supplied both to the operating circuit 60 and also to the illumination module 28 by means of a combined connection and contact element 98.

FIG. 12 and FIG. 13 illustrate operating circuits 60, each of which has a printed circuit board 63 and the first printed circuit board contact surface 70a and the second printed circuit board contact surfaces 70b. According to FIG. 12, a combined connection and contact element 98 is used to provide a supply potential both for the operating circuit 60 and also for the illumination module 28. A connection element 83 is present to provide a second supply potential for the operating circuit 60. Moreover, multiple—according to the example three—connection elements 72 are used, to convey output-side signals of the operating circuit 60 to the illumination module 28.

In the exemplary embodiment illustrated in FIG. 13, the combined connection and contact element 98 of the exemplary embodiment from FIG. 12 is replaced by a connection element 83. According to the example, two contact elements 72 are used, to convey output-side signals of the operating circuit 60 to the illumination module 28.

The exemplary embodiments according to FIG. 12 and FIG. 13 are only examples. At least one contact element 72 and/or at least one connection element 83 and/or at least one combined connection and contact element 98 can be arranged in any combination, depending on whether a conductor 93 connected with the illumination module assembly 15 should be connected only with the operating circuit 60 (exemplary embodiment according to FIG. 8), only with the illumination module 28 (exemplary embodiment according to FIGS. 6 and 7 or alternatively exemplary embodiment according to FIG. 5 or alternatively combination of the exemplary embodiments according to FIG. 8 and FIG. 9 or FIG. 10) or both with the operating circuit 60 and also with the illumination module 28 (exemplary embodiment according to FIG. 5). All variants are possible. Moreover, a connection can be made between the output connections of the operating circuit 60 and the illumination module 28 through the contact elements 72. If the output signal should be used for other illumination modules of other illumination module assemblies, here it is for example also possible to use the combined connection and contact elements 98 and to forward the output signal of the operating circuit 60 not only to the illumination module 28 of this illumination module 15, but rather also to other external illumination modules through corresponding conductors 93.

Assembly of the illumination module assembly 15 to a base surface 38 at an installation site is very simple. First, the first housing part 17 is fastened to the base surface 38 with the fastening components 36 or the screws 37. Then, the illumination module 28 can be inserted into the positioning window 27. The printed circuit board 63 with the components 61 forms a unit with the second housing part 18. Depending on how many external conductors 93 should be connected, correspondingly many connection elements 83 are arranged or inserted, each in one holding area 82 adjacent to a connection socket 81. Then, the second housing part 18 with the operating circuit 60 and the connection elements 83 is connected with the first housing part 17, according to the example by a latching connection. This makes the electrical connection between the operating circuit 60 and the illumination module 28 by means of the contact elements 72. Finally, two or more conductors 93 can be inserted through the corresponding connection sockets 81. The insertion of the conductors 93 is also possible already before the two housing parts 17, 18 are connected.

The above-described illumination module assembly 15 allows a space-saving arrangement of an operating circuit 60 in the second housing part 18. The fact that the operating circuit 60 is handled as a unit with the second housing part 18 and the fact that the mechanical connection of the two housing parts 17, 18 is made simultaneously with the electrical connection between the operating circuit 60 and the illumination module 28 allows very simple assembly of the illumination module assembly 15 at the installation site. The option of arranging the connection elements 83 in the holding areas 82 that are present or the option of arranging the contact elements 72 on the operating circuit 60 or the printed circuit board 63 makes it simple to adapt the illumination module assembly 15 to the respective application case.

The present disclosure relates to an illumination module assembly 15 including a first housing part 17 and a second housing part 18 which can be mechanically connected with one another. The first housing part 17 has a positioning window 27 to hold an illumination module 28 with a lamp assembly 29 made of at least one semiconductor lamp. The second housing part 18 has a light exit opening 48 that is bordered by an inner wall section 45. The inner wall section 45 is surrounded in a peripheral direction U by an outer wall section 46. The two wall sections 45, 46 are connected with one another through a connecting wall section 47. The three wall sections 45, 46, 47 form an installation space 65 for an operating circuit 60 that has a printed circuit board 63 and at least one electrical and/or electronic component 61. The at least one component 61 is arranged on a component side 62 of the printed circuit board 63. The printed circuit board 63 is arranged with its printed circuit board bottom 64, which is opposite the component side 62, facing the connecting wall section 47 that is between the inner wall section 45 and the outer wall section 46, so that when a connection is made between the housing parts 17, 18 the component side 62 faces the first housing part 17. The operating circuit 60 and the second housing part 18 form a unit that allows them to be handled together and connected with the first housing part 17.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. An illumination module assembly, comprising:
a first housing part that includes a connector and can be fastened to a base surface by a fastening component, the first housing part including a positioning window, into which an illumination module is inserted;
a second housing part that includes a counterpart connector, which is configured to create a connection with the connector of the first housing part, the second housing part including an inner wall section bordering a light exit opening, an outer wall section surrounding the inner wall section in a peripheral direction, and a connecting wall section that connects the inner wall section and the outer wall section;
an operating circuit that includes at least one component and is configured to operate the illumination module, the at least one component of the operating circuit being arranged on a component side of a printed circuit board, wherein
the printed circuit board is fastened to the second housing part and arranged between the inner wall section and the outer wall section, such that a printed circuit board bottom opposite the component side faces the connecting wall section.

2. The illumination module assembly according to claim 1, wherein
the printed circuit board is fastened to the second housing part by a sealing compound.

3. The illumination module assembly according to claim 1, wherein
the printed circuit board bottom abuts against the connecting wall section.

4. The illumination module assembly according to claim 3, wherein
the printed circuit board bottom two-dimensionally abuts against or is connected with the connecting wall section.

5. The illumination module assembly according to claim 4, wherein
the printed circuit board bottom is connected with the connecting wall section by an adhesion connection.

6. The illumination module assembly according to claim wherein
the printed circuit board and the at least one component of the operating circuit are arranged completely inside an installation space, which is bordered by the inner wall section, the outer wall section, and the connecting wall section.

7. The illumination module assembly according to claim wherein
at least one electrically conductive printed circuit board contact surface is present on the component side of the printed circuit board, and
one contact element which is electrically conductive is electrically connected with each of the printed circuit board contact surfaces.

8. The illumination module assembly according to claim 7, wherein
the contact element is configured to make an electrical connection between the operating circuit and the illumination module.

9. The illumination module assembly according to claim 7, wherein
the contact element includes a first contact section electrically connected with the printed circuit board contact surfaces associated, a contact spring extending away from the first contact section, and a second contact section on an end of the contact spring opposite to the first contact section.

10. The illumination module assembly according to claim 9, wherein
the contact spring is elastically movable in a direction toward the positioning window and away from the positioning window, and is configured to abut with the second contact section against an associated electrically conductive module contact surface of the illumination module if the first housing part and the second housing part have been connected and if the illumination module has been inserted in the positioning window.

11. The illumination module assembly according to claim 1, wherein
the second housing part includes at least one connection socket, each of which is followed, between the outer wall section and the inner wall section and adjacent to the connection socket, by one holding area that is configured to hold one electrically conductive connection element.

12. The illumination module assembly according to claim 11, wherein
at least one holding area has an electrically conductive connection element arranged in the at least one holding area.

13. The illumination module assembly according to claim 11, wherein
every connection element has a clamping assembly arranged behind an inner opening of an associated connection socket among the at least one connection socket, in an insertion direction of the associated connection socket.

14. The illumination module assembly according to claim 11, wherein
every connection element includes a contact part that abuts against one associated electrically conductive printed circuit board contact surface of the printed circuit board.

15. The illumination module assembly according to claim 11, wherein
every connection element is held at the second housing part in a force-fit and/or form-fit manner.
